(19) United States
(12) Patent Application Publication
(10) Pub. No.: US 2011/0165747 A1
(43) Pub. Date: Jul. 7, 2011

(54) SEMICONDUCTOR APPARATUS AND FABRICATION METHOD THEREOF

(75) Inventor: Kyung Do KIM, Seoul (KR)

(73) Assignee: Hynix Semiconductor Inc., Icheon (JP)

(21) Appl. No.: 12/840,027

(22) Filed: Jul. 20, 2010

(30) Foreign Application Priority Data
Jan. 7, 2010 (KR) 10-2010-0001212

(51) Int. Cl. H01L 21/336

(52) U.S. Cl. 438/270; 257/E21.41

(57) ABSTRACT

A method for manufacturing a semiconductor apparatus includes forming a contact pad layer over a substrate in an active region; patterning the contact pad layer and the substrate to form a first trench, the first trench defining a contact pad pattern; etching the substrate to form a second trench that extends vertically from the first trench; forming a gate insulating pattern over the substrate in the second trench; and forming a buried gate in the second trench.

### CROSS-REFERENCE TO RELATED APPLICATION

Priority is claimed to Korean patent application number 10-2010-0001212, filed on Jan. 7, 2010, which is incorporated by reference in its entirety.

### FIELD OF THE INVENTION

The present invention relates to a method of manufacturing a highly integrated semiconductor apparatus, and more specifically, to a method for increasing integrity of a semiconductor apparatus including a buried word line structure, thereby improving operational reliability of the semiconductor apparatus.

### BACKGROUND OF THE INVENTION

A semiconductor memory apparatus includes a plurality of unit cells each including a capacitor and a transistor. A double-capacitor device has been used to temporarily store data. A transistor is a device which transmits data between a bit line and a capacitor in response to a control signal (word line) using electric conductivity-characteristics of the semiconductor material. The transistor has three regions including a gate, a source and a drain, where charges move between the source and the drain in response to a control signal inputted to the gate. The charges between the source and the drain move through a channel region.

For a typical transistor, a gate is formed in the semiconductor substrate, and impurities are doped at both sides of the gate to form a source and a drain. To meet the needs for increased data capacity and higher integration of a semiconductor memory apparatus, the size of a unit cell is required to be made smaller. That is, the design rule for a unit cell is decreased. As a result, a channel length of a transistor becomes shorter, and a shortened channel length causes a short channel effect and a drain-induced-barrier-lower (DIBL) effect that hinders the normal operation of the chip.

For preventing the short channel effect and the DIBL effect, the doping concentration in the channel region has been increased to meet a threshold voltage required for a cell transistor. However, as the design rule is decreased to less than 100 nm, the increased doping concentration in the channel region causes an electric field in a storage node (SN) junction to increase and thus degrades a refresh characteristic of the semiconductor memory apparatus. In order to prevent the degradation of the refresh characteristic, a cell transistor with a three-dimensional configuration has been suggested. With a three-dimensional configuration, a long channel length can be secured even under a reduced design rule. Moreover, since a long channel length can be secured, doping concentration can be adjusted to a lower level, thus preventing degradation of refresh characteristics. For an example of three-dimensional transistors, a process for forming a saddle-type fin transistor will be described.

Meanwhile, as a semiconductor memory device becomes more highly integrated, a distance between a word line and a bit line becomes narrower. Thus, a parasitic capacitance between the word line and the bit line increases, and an operation margin of a sense amplifier which senses and amplifies data transmitted through the bit line is deteriorated. Finally, an operation reliability of the semiconductor memory device is degraded.

For reducing the parasitic capacitance between the word line and the bit line, a buried word line structure has been suggested. In a buried word line structure, a word line is completely buried in a semiconductor substrate. A word line material is deposited to fill up a lower part of a recess formed in a semiconductor substrate and an insulating material is then formed to fill up an upper part of the recess. A bit line is formed over the semiconductor substrate. Thus, the word line may be separated from the bit line by the insulating material.

FIG. 1 is a cross-sectional view showing a conventional semiconductor device having a buried gate.

As shown, the semiconductor device includes a device isolation layer 104, formed by a shallow trench isolation (STI) method, for defining an active region in a semiconductor substrate 102. A recess is formed in the active region and the device isolation layer 104, a gate oxide layer 120 is formed, and a buried gate 116 including a metal such as TiN is formed over the oxide layer 120 to fill up the lower part of the recess. An insulating layer 118 including SiO₂ is formed over the buried gate 116 in the recess. Source/drain regions 122 including N-type dopants are formed at both sides of the buried gate 116 in the active region.

Over the source/drain regions 122, a contact pad 110 is formed, and a capacitor or a bit line electrically coupled to the contact pad 110 is formed. In order to form the contact pad 110, an inter-layer insulating layer (not shown) is deposited over the source/drain regions 122 and the insulating layer 118, and then a contact hole (not shown) defining an area for the contact pad 110 is formed. Herein, the contact hole is formed to expose the source/drain regions 122. By filling up conductive material in the contact hole, the contact pad 110 is formed.

In a conventional method, it takes a lot of time and cost to form a contact pad 110 because the method for forming the contact pad 110 is as complicated as fabricating the buried gate 116. Particularly, since a gap between neighboring buried gates 116 in a highly integrated semiconductor device is very narrow, it is not easy to form a contact hole (exposing source/drain regions) at a precise location. If the contact hole is formed misaligned, contact resistance between the contact pad 110 and the source/drain regions 122 increases. Furthermore, when the inter-layer insulating layer is over-etched from being misaligned, the source/drain regions 122 and even the buried gate 116 may get attacked. Accordingly, operational reliability of the semiconductor apparatus deteriorates.

### SUMMARY OF THE INVENTION

An embodiment of the present invention is directed to a semiconductor device and a method for manufacturing the semiconductor device, which is configured to increase a process margin for forming a contact and reduce the number of steps for forming the contact so that operational reliability and productivity are increased.

In accordance with an embodiment of the present invention, a method for manufacturing a semiconductor apparatus comprises forming a device isolation layer configured to define an active region in a semiconductor substrate, forming contacts on the active region, and forming a buried gate between the contacts.

According to an embodiment, the forming a device isolation layer comprises depositing a pad insulating layer over the semiconductor substrate, and etching the pad insulating layer and the semiconductor substrate and depositing an insulating layer, to form the device isolation layer configured to define the active region.

According to an embodiment, the forming contacts on the active region comprises removing the pad insulating layer, depositing a poly silicon over the active region and the device isolation layer, planarizing the poly silicon until a top surface of the device isolation layer is exposed, and etching a partial of the poly silicon to expose the semiconductor substrate. The poly silicon can be doped by N type dopants of 1e19 to 9e20/cm³.

According to an embodiment, the etching a partial of the poly silicon comprises depositing an insulating layer over the poly silicon, etching the insulating layer by using a mask defining a location of the buried gate, and etching the poly silicon and a partial of the semiconductor substrate by using the etched insulating layer as an etch mask. A recess formed by etching the partial of the semiconductor substrate can have a 10% to 90% depth of the buried gate. According to an embodiment, the forming a buried gate between the contacts comprises forming nitride layers on sidewalls of the contacts, etching the semiconductor substrate between the nitride layers to form a recess, forming an oxide layer on the semiconductor substrate exposed by the recess, depositing a conductive material in a lower part of the recess, and depositing an insulating material over the conductive material in the recess.

According to an embodiment, the conductive material comprises one of poly silicon, aluminum, tungsten, and titanium; and the insulating material comprises one of spin on dielectric material, spin on carbon material, and SiO₂.

According to an embodiment, the depositing a conductive material comprises depositing the conductive material in the recess, performing an etch back process to remove a partial of the conductive material at a upper part of the recess, and performing a clean process to the upper part of the recess after the etch back process. The recess is formed by an anisotropy etch method performed on the active region.

According to an embodiment, the method further comprises diffusing dopants included in the contacts into the active region to form source/drain regions.

### BRIEF DESCRIPTION OF THE DRAWINGS

FIG. 1 is a cross-sectional view showing a conventional semiconductor device having a buried gate.

FIGS. 2 to 4 are cross-sectional views showing a method for fabricating a semiconductor device according to an embodiment of the present invention.

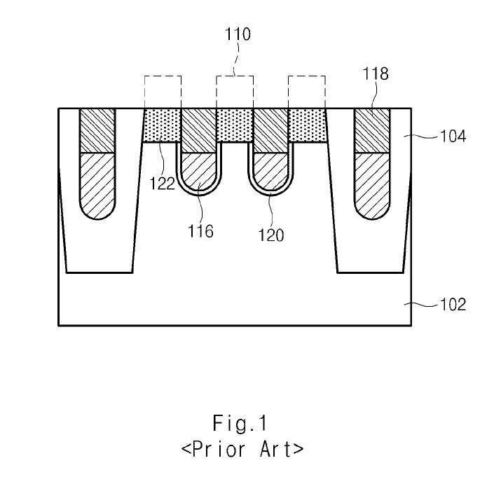

### DESCRIPTION OF SPECIFIC EMBODIMENTS

Embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will convey the scope of the present invention to those skilled in the art. Like reference numerals refer to like parts throughout the various figures and embodiments of the present invention.

In an embodiment of the present invention, a semiconductor apparatus includes a buried gate. According to a method for manufacturing a semiconductor apparatus, process steps for forming contacts over a cell transistor included in a unit cell can be reduced or simplified so that a process margin for each step may be increased. Accordingly, operational reliability and performance of the semiconductor apparatus manufactured by the above method can be improved. Hereinafter, embodiments of the present invention are described with reference to the accompanying drawings.

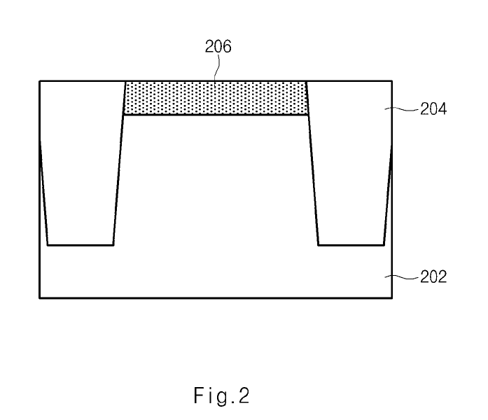

FIGS. 2 to 4 are cross-sectional views showing a method for fabricating a semiconductor device according to an embodiment of the present invention.

Referring to FIG. 2, a device isolation layer 204 for defining an active region is formed over a semiconductor substrate 202. For example, the device isolation layer 204 can be formed by a Shallow Trench Isolation (STI) method. First, a pad insulating layer 206 including a pad oxide layer and a pad nitride layer is deposited over the semiconductor substrate 202. Then, a photo-resist layer (not shown) is formed over the pad insulating layer 206. The photoresist layer (not shown) is then patterned by using a mask which defines the active region to form a photoresist pattern. The pad insulating layer 206 is patterned using the photoresist pattern as an etching mask to form a pad insulating pattern. Then, the semiconductor substrate 202 exposed by the pad insulating pattern is etched to form a trench. Then, a spin-on-dielectric (SOD) material is deposited over the trench and the pad insulating pattern and is planarized until the pad insulating layer 206 is exposed, thus forming the device isolation layer 204.

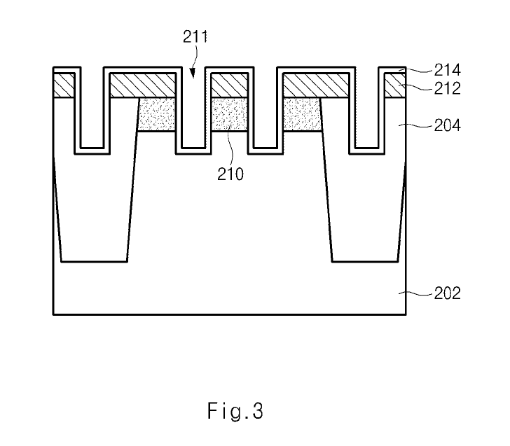

Referring to FIG. 3, a contact pad 210 is formed. In detail, after the device isolation layer 204 is formed, the pad insulating layer 206 is removed to expose an active region. Over the semiconductor substrate 202 in the active region, a doped polysilicon layer is deposited and planarized until the device isolation layer 204 is exposed. The doped poly-silicon can be obtained by doping poly-silicon with N-type dopants with an energy of about 1e19 to 9e20/cm³. Then, an inter-layered insulating layer is deposited over the device isolation layer 204 and the poly-silicon layer.

Using a mask to define a buried gate, the inter-layered insulating layer, the poly-silicon layer and the semiconductor substrate 202 are subsequently patterned to form a first trench 211. In the present embodiment, the semiconductor substrate 202 is etched to about 10 to 90% of the total depth of the first trench 211 that defines the buried gate. In another embodiment, the semiconductor substrate 202 is etched to 20 to 60% of the total depth of the first trench 211. As a result, the inter-layered insulating layer and the poly-silicon layer are patterned to form an inter-layered insulating pattern 212 and the contact pad 210, respectively. After the contact pad 210 is formed, a nitride layer 214 having a substantially uniform thickness is formed over the device isolation layer 204, the inter-layered insulating pattern 212 and sidewalls of the contact pad 210. The nitride layer 214 provides a conformal coating to the structures defined by the first trench 211.

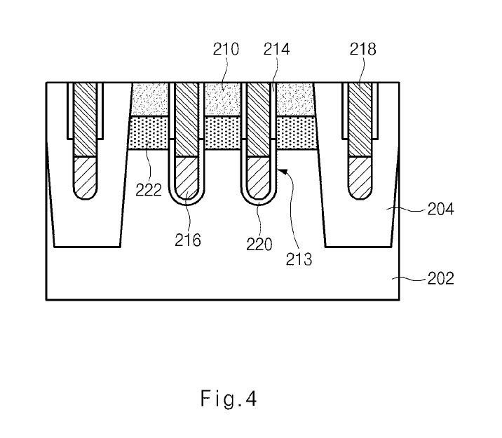

Referring to FIG. 4, the substrate 202 under the first trench is further etched to form a second trench 213. The second trench 213 is formed using an anisotropy blanket etch method in the present embodiment. After the second trench 213 is formed, a gate oxide layer 220 is formed over the substrate in the second trench.

Conductive material such as poly silicon, aluminum, tungsten, and titanium is formed over the gate oxide layer 200 to fill up the lower part of the second trench, thus forming a buried gate 216. The buried gate 216 can be formed by filling up the conductive material in the second trench and performing an etch back process. An insulating pattern 218 is formed over the buried gate 216 by filling up the upper portion of the second trench. The insulating pattern 218 can be formed by using insulating material such as spin on dielectric material, spin on carbon material, or SiO₂ in the upper portion of the second trench and then performing a planarization process. The inter-layered insulating pattern 212 and the nitride layer 214 are subject to a planarization process to expose the contact pad 210.

After the contact pad 210 and the buried gate 216 are formed, source/drain regions 222 are formed under the contact pad 210 in the active region. The source/drain regions 222 can be formed by diffusing N-type dopants included in the contact pad 210. For example, for the diffusion of N-type dopants, an annealing process can be performed.

As above described, in accordance with an embodiment of the present invention, a contact pad which is electrically coupled to source/drain regions can be self-aligned at the time when a buried gate is formed. Accordingly, defects due to an insufficient process margin or mis-alignment occurring when a contact pad is formed by a separate additional process may be reduced or prevented.

In the present invention, since the contact pad 210 is formed in a self-aligned fashion at the time when the second trench for the buried gate is formed, the number of process steps may be saved and an overall process becomes simplified.

Moreover, because the present invention is free from defects due to mis-alignment, a contact resistance between the source/drain regions and the contact pad may be kept at a desired level so that operational reliability of the semiconductor apparatus can be improved.

While the present invention has been described with respect to the specific embodiments, it will be apparent to those skilled in the art that various changes and modifications may be made without departing from the spirit and scope of the invention as defined in the following claims.

What is claimed is:

1. A method for manufacturing a semiconductor apparatus, comprising:
forming a contact pad layer over a substrate in an active region;
patterning the contact pad layer and the substrate to form a first trench, the first trench defining a contact pad pattern;
etching the substrate to form a second trench that extends vertically from the first trench; and
forming a buried gate in the second trench.

2. The method according to claim 1, further comprising forming a first insulating layer over a sidewall of the first trench prior to etching the substrate to form the second trench.

3. The method according to claim 2, wherein the first insulating layer includes a silicon nitride layer.

4. The method according to claim 1, further comprising forming a gate oxide layer over the substrate in the second trench.

5. The method according to claim 4, wherein the buried gate is formed in a lower portion of the second trench and the gate oxide layer extends into an upper portion of the second trench.

6. The method according to claim 1, wherein the active region is defined by a device isolation layer, the device isolation layer is formed by:
forming a pad insulating layer over the substrate;
patterning the pad insulating layer and the substrate to form an isolation recess; and
forming the device isolation layer in the isolation recess.

7. The method according to claim 1, wherein the contact pad pattern includes doped-polysilicon.

8. The method according to claim 7, wherein the doped poly-silicon is doped with N-type dopants by an implantation process performed at an energy level between 1e19 to 9e20/cm³.

9. The method according to claim 7, further comprising applying dopants into the contact pad pattern to form source/drain regions.

10. The method according to claim 1, wherein the step of forming the first trench comprises
forming a second insulating layer over the contact pad layer;
patterning the second insulating layer by using a mask defining the area defined for the buried gate to form a second insulating pattern; and
patterning the contact pad layer and the substrate under the contact pad layer by using the second insulating pattern as a mask.

11. The method according to claim 1, wherein a depth of the substrate etched to form the first trench is no more than 90% of a depth of the first trench.

12. The method according to claim 1, wherein the step of forming the buried gate comprises:
providing conductive material into the second trench;
performing an etch-back process to remove the conductive material provided in an upper portion of the second trench, so that the buried gate is defined entirely in a lower portion of the second trench; and
forming a third insulating pattern over the buried gate in the second trench.

13. The method according to claim 12, wherein the buried gate comprises any of polysilicon, aluminum, tungsten, and titanium; and
wherein the third insulating pattern comprises any of spin-on-dielectric material, spin-on-carbon material, and SiO₂.

14. The method according to claim 1, wherein the first trench is formed by an anisotropy etch method.

15. The method according to claim 1, wherein the contact pad pattern is self-aligned when the contact pad layer and the substrate are patterned to form the first trench.
